(19) United States
(12) Patent Application Publication
(10) Pub. No.: US 2006/0164141 A1
(43) Pub. Date: Jul. 27, 2006

(54) Controlled delay line circuit with integrated transmission line reference

(76) Inventor: Paul William Ronald Self, Santa Clara, CA (US)

Correspondence Address: Chad R. Walsh, Suite 509, 900 Lafayette Street, Santa Clara, CA, 95050, US

(21) Appl. No.: 11/329,779

(22) Filed: Jan. 11, 2006

Related U.S. Application Data
(60) Provisional application No. 60/645,837, filed on Jan. 21, 2005.

(51) Int. Cl. H03L 7/06

(52) U.S. Cl. 327/158

(57) ABSTRACT

Embodiments of the present invention include a controlled delay line circuit comprising a feedback loop including an integrated transmission line, wherein the integrated transmission line is used as a timing reference for the feedback loop and wherein the feedback loop and the transmission line are integrated on a single integrated circuit. The feedback loop may be a Delay Locked Loop, for example.

### CROSS REFERENCE TO RELATED APPLICATIONS

This invention claims the benefit of priority from U.S. Provisional Application No. 60/645,837, filed Jan. 21, 2005, entitled “Controlled Delay Line Circuit with Integrated Transmission Line Reference.”

### BACKGROUND

The present invention relates to controlled delay lines, and in particular, to a controlled delay line circuit with an integrated transmission line reference.

One of the most important issues in the design of the digital logic section of an integrated circuit is the system clock to data timing relationship. In order to optimize this important timing relationship, a controlled delay line is often used. The controlled delay line is used to delay the data and/or the system clock in such a way as to improve the timing relationship. For example, one common type of controlled delay line that is often used is a voltage controlled delay line (VCDL). Voltage controlled delay lines are advantageous because the delay time of a VCDL is relatively accurate, predictable, and stable. The accuracy and stability of the voltage controlled delay line depends on how the control voltage for the VCDL is generated. The control voltage is typically created using a reference VCDL within the feedback loop of a Delay Locked Loop (DLL). The DLL forces the reference VCDL to have the same time delay as the timing reference for the DLL. The timing reference for the DLL is usually the period of the system clock or some multiple of this period. Since the system clock is normally oscillating at a very precise and stable frequency, this results in the delay time of the VCDL also being relatively precise and stable.

In some applications, there is a requirement that the digital logic of an integrated circuit has to operate at more than one system clock frequency. If the system clock shifts to a new frequency, the delay time of the VCDL could also change if it is dependent on the period of the system clock. This change in delay time for the VCDL may adversely affect the system clock to data timing relationships. For this design situation, a voltage controlled delay line that is independent of the system clock would be advantageous.

One possible method to create a VCDL that is not dependent on the system clock is to use a resistor and capacitor network as a timing reference device for the Delay Locked Loop. Even though a resistor and capacitor network can be integrated into an integrated circuit, the repeatability and stability of an integrated resistor and capacitor network's RC time constant is poor. An integrated circuit RC time constant can vary quite a lot due to variations in the manufacturing process. For example, such manufacturing process variations may cause the value of an integrated resistor to vary as much as ±20% and the value of an integrated capacitor can vary as much as ±10%. These large variations in the values of the integrated resistors and capacitors mean that the precision of an integrated circuit RC time constant is low. Moreover, the value of an integrated resistor can change significantly over a temperature range. The value of an integrated resistor will typically change by 7% over a temperature range of 70 degrees Celsius. Thus, the RC time constant of an integrated circuit resistor and capacitor network is not very stable across a temperature range. Because of the wide changes in value due to manufacturing and temperature variations, an integrated circuit resistor and capacitor network would not make a good timing reference for an integrated DLL.

Thus, there is a need for an improved controlled delay line circuit that is repeatable, stable across manufacturing processes, and independent of the system clock.

### SUMMARY

Embodiments of the present invention include a controlled delay line circuit comprising a feedback loop including an integrated transmission line, wherein the integrated transmission line is used as a timing reference for the feedback loop and wherein the feedback loop and the transmission line are integrated on a single integrated circuit. The feedback loop may be a Delay Locked Loop, for example.

In one embodiment, the present invention includes an integrated circuit comprising a first controlled delay line coupled in a feedback loop and an integrated transmission line, and the integrated transmission line is used as a timing reference for the feedback loop and wherein the feedback loop and the transmission line are integrated on a single integrated circuit.

In one embodiment, the feedback loop includes a phase detector having a first input coupled to an output of the integrated transmission line and a second input coupled to an output of the first controlled delay line.

In one embodiment, the first controlled delay line and the integrated transmission line have inputs that are coupled to a circuit that generates a first periodic signal.

In one embodiment, the circuit further comprises a phase-frequency detector having a first input coupled to an output of the integrated transmission line and a second input coupled to an output of the first controlled delay line, a charge pump coupled to an output of the phase-frequency detector, and a capacitor coupled to the output of the charge pump and to a control input of the first controlled delay line.

In one embodiment, the circuit further comprise a second controlled delay line having a control input coupled to the control input of the first controlled delay line.

In one embodiment, the second controlled delay line receives an input signal, and generates a delayed version of said input signal.

In one embodiment, the present invention includes an integrated circuit comprising an integrated transmission line having an input coupled to receive a periodic signal, the transmission line delaying the periodic signal by a first delay to produce a first delayed signal, a first controlled delay line having a first input coupled to the periodic signal and a first control input, the first controlled delay line delaying the periodic signal by a first variable delay to produce a second delayed signal, a phase detector having a first input coupled to an output of the integrated transmission line and a second input coupled to an output of the first controlled delay line, and a filter coupled between an output of the phase detector and the control input of the first controlled delay line.

In one embodiment, the phase detector, the first controlled delay line, and the transmission line are integrated on a single integrated circuit.

In one embodiment, the integrated transmission line comprises one or more conductive interconnect layers.

In one embodiment, wherein the filter is a capacitor.

In one embodiment, the circuit further comprises a second controlled delay line having a control input coupled to the filter.

In one embodiment, the phase detector is a phase-frequency detector coupled to a charge pump.

In one embodiment, the periodic signal is generated by an oscillator circuit, and the phase-frequency detector includes an enable input coupled to the oscillator circuit.

In one embodiment, the present invention includes a method of controlling the delay of a signal comprising generating a first signal, delaying the first signal by a first delay in an integrated transmission line to produce a first delayed signal, and delaying the first signal by a first variable delay in a first controlled delay line to produce a second delayed signal, wherein the first controlled delay line is configured in a feedback loop, wherein the integrated transmission line is used as a timing reference for the feedback loop to adjust the first variable delay to be equal to the first delay, and wherein the feedback loop and the transmission line are integrated on a single integrated circuit.

In one embodiment, the method further comprises delaying a second signal by a second variable delay in a second controlled delay line.

In one embodiment, the second variable delay is equal to the first variable delay.

In one embodiment, the method further comprises detecting a phase difference between the first delayed signal and the second delayed signal.

In one embodiment, the method further comprises increasing the first variable delay if the first delay is greater than the first variable delay, and decreasing the first variable delay if the first delay is smaller than the first variable delay.

In one embodiment, a time difference between the first delayed signal and the second delayed signal is translated into a voltage on a capacitor and used to control the first variable delay.

In one embodiment, the method further comprises generating a first pulse in response to the first delayed signal and generating a second pulse in response to the second delayed signal, discharging a current from a capacitor in response to receiving the first pulse, and charging a current into a capacitor in response to receiving the second pulse, and in accordance therewith, changing a first voltage on the capacitor, and adjusting the first variable delay using the first voltage on the capacitor.

In one embodiment, the present invention includes an integrated circuit comprising transmission line means for delaying a periodic reference signal means by a fixed amount of time, controlled delay line means for delaying the periodic reference signal means by a first variable amount of time, and feedback loop means for adjusting the first variable amount of time to equal the-fixed amount of time, wherein the transmission line means, the controlled delay line means, and the feedback loop means are integrated on a single integrated circuit.

The following detailed description and accompanying drawings include illustrations and examples that provide a better understanding of the nature and advantages of the present invention.

### BRIEF DESCRIPTION OF THE DRAWINGS

FIG. 1A illustrates an integrated transmission line used as a timing reference in a feedback loop according to one embodiment of the present invention.

FIG. 1B illustrates a controlled delay line with an integrated transmission line reference according to one embodiment of the present invention.

FIG. 2 is an example of a phase detector according to one embodiment of the present invention.

FIG. 3 is a timing diagram to illustrate the operation of a controlled delay line according to one embodiment of the present invention.

FIG. 4 is another timing diagram to illustrate the operation of a controlled delay line according to one embodiment of the present invention.

### DETAILED DESCRIPTION

Described herein are techniques for improving voltage controlled delay lines on an integrated circuit. In the following description, for purposes of explanation, numerous examples and specific details are set forth in order to provide a thorough understanding of the present invention. It will be evident, however, to one skilled in the art that the present invention as defined by the claims may include some or all of the features in these examples alone or in combination with other features described below, and may further include obvious modifications and equivalents of the features and concepts described herein.

Embodiments of the present invention include building an integrated transmission line (ITL) into an integrated circuit as the timing reference device. The flight time delay of the transmission line may be used as a timing reference for a DLL on the same chip. Time delay in a transmission line is caused by the propagation of electromagnetic waves down the transmission line. Such time delays may further include some delay caused by parasitic resistances of the delay line. Embodiments of the present invention may preferably minimize the delay effects of parasitic resistances because such resistances may cause the time delay of an integrated transmission line to vary across process and temperature. More generally, the flight time delay of a transmission line depends on a variety of parameters, including geometric shape, length, construction, and the relative dielectric constant of the transmission line's insulator. One common transmission line is stripline. The flight time delay for a stripline transmission line can be calculated from the following equation:
τ_{TL}=(L_{TL}(ε_{τ})^{1/2})/cₒ
where,
T_{TL}=flight time delay of the transmission line
L_{TL}=length of the transmission line
ε_{τ}=relative dielectric constant of the transmission line insulator.
cₒ=the speed of light in a vacuum.
These equations apply to transmission lines with fields contained in a single dielectric. Examples of such transmission lines include stripline and coax. However, these equations are illustrative only. The present invention may use any integrated transmission line that produces a stable time delay, such as microstrip, for example, and others.

Stability and repeatability advantages of using an integrated transmission line in a frequency generator can be seen by examining the terms of the flight time delay equation. The length of the integrated transmission line, L_{TL}, may be set by design choice. Once the value of the term L_{TL} is designed, an integrated transmission line will have negligible changes in length due to variations in the manufacturing of the integrated circuit.

With regard to the other parameters effecting flight time delay, the term cₒ is the speed of light in a vacuum, which is a physical constant that is invariable. The value of the term ε_{τ} depends on the dielectric material used as the insulator for the integrated transmission line. In the current manufacturing environment, the most common insulator for a transmission line on an integrated circuit would be amorphous silicon dioxide. The relative dielectric constant, ε_{τ}, for silicon dioxide does not change with manufacturing variations and exhibits only a very small variation due to temperature changes. The temperature coefficient for silicon dioxide's relative dielectric constant is approximately 20 ppm/° C. The variation of ε_{τ} due to temperature change translates into a temperature coefficient for τ_{TL} of approximately 10 ppm/° C. For a 70° C. change in temperature, the total variation of τ_{TL} should be less than 0.1% due to the variation in ε_{τ}.

Another advantage of an integrated transmission line is that the time delay of an integrated transmission line is not dependent on the magnitude of the signal that is propagating along the transmission line. Thus, the time delay, τ_{TL}, is independent of the power supply voltage of the integrated circuit. Thus, because the flight time delay of a transmission line is independent of the power supply voltage, exhibits very good stability versus temperature change, and changes very little due to manufacturing variations, the flight time delay of an integrated transmission line would make a good timing reference for an integrated DLL. Therefore, embodiments of the present invention advantageously include a voltage controlled delay line with an integrated transmission line as the timing reference.

In some embodiments, the present invention may use one or more conductive interconnect layers (e.g., metalization) for constructing an integrated circuit transmission line. For example, connecting multiple metalization layers in parallel can reduce the resistance of the integrated transmission line, resulting in an improved transmission line. One common metalization material is aluminum. Additionally, other processes may use one or more copper metalizations as the transmission line. Since copper has a lower sheet resistance than aluminum, the use of copper for the integrated transmission line can reduce its resistance even more. Of course, other conductive materials could be used. Furthermore, embodiments of the present invention may use very high speed transistor devices. These fast devices allow the designer to create on-chip high-speed components included in a voltage controlled delay line with an integrated transmission line as a timing reference device.

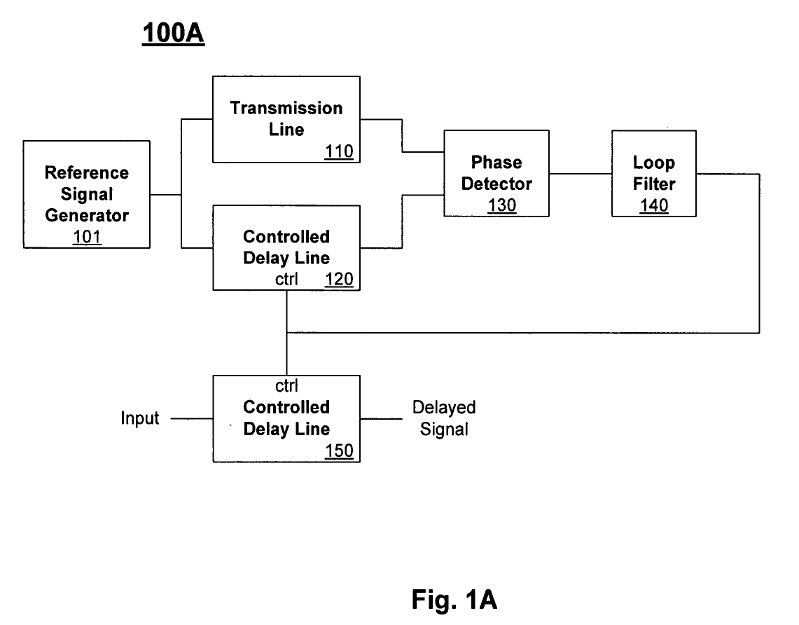

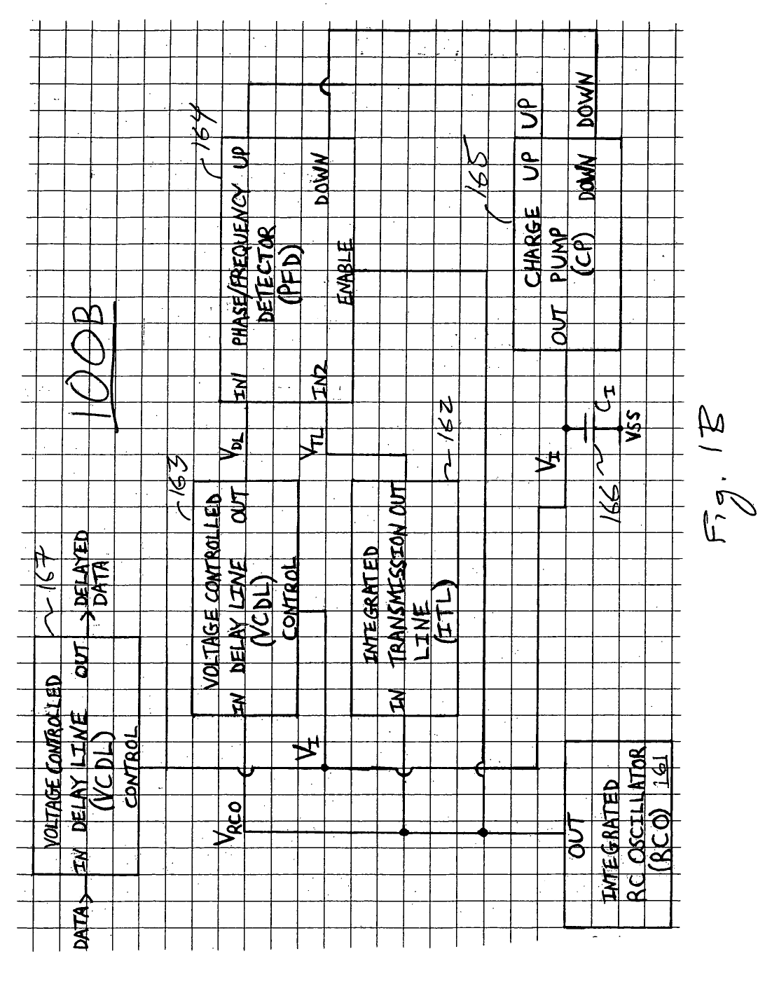

FIG. 1A illustrates an integrated transmission line used as a timing reference in a feedback loop according to one embodiment of the present invention. In one embodiment, the present invention includes an integrated circuit comprising a first controlled delay line 120 coupled in a feedback loop and an transmission line 110, where the transmission line is used as a timing reference for the feedback loop. In one embodiment, the feedback loop and the transmission line are integrated on a single integrated circuit. The feedback loop may further include a phase detector 130 and loop filter 140. Phase detector 130 includes a first input coupled to an output of transmission line 110 and a second input coupled to an output of controlled delay line 120. The output of phase detector 130 is coupled to loop filter 140. The loop filter may include a capacitor, for example. The output of loop filter 140 is used to control the delay of controlled delay line 120.

In one embodiment, a reference signal generator 10 may be used to generate a reference signal, which may be a periodic signal such as a square wave, for example. The reference signal is provided to the inputs of transmission line 110 and controlled delay line 120. Transmission line 110 delays the reference signal by a certain delay dependent on the characteristics of the transmission line. The controlled delay line 120 delays the reference signal by a delay that is a function of the signal received on the control input (“ctrl”). Phase detector 130 receives a first delayed signal from the transmission line and a second delayed signal from the controlled delay line. Phase detector 130 may be used to detect a phase difference between the two delayed signals. The output of phase detector 130 may be filtered in loop filter 140, and the output of loop filter 140, which may represent the difference in delay between transmission line 110 and controlled delay line 120, may be coupled to the control input of controlled delay line 120. Thus, the loop increases the delay of the controlled delay line if the transmission line delay is greater than the delay of the controlled delay line. Similarly, the loop decreases the delay of the controlled delay line if the transmission line delay is less than the delay of the controlled delay line. The action of the feedback loop will cause the delay of the controlled delay line 120 to be equal to the delay of the transmission line 110. The control signal generated by the loop filter, which is used to control the delay line 120, may also be used to control the delay of one or more other delay lines 150. The other delay lines may receive input signals, such as digital data signals or system clocks, for example, and delay the input signals by an amount of time that is related to the delay of controlled delay line 120.

FIG. 1B illustrates a controlled delay line circuit with an integrated transmission line reference according to one embodiment of the present invention. In one embodiment, the present invention includes an integrated circuit that uses a feedback loop to force a controlled delay line to have a time delay that is equal to the flight time delay of the integrated transmission line (ITL). While the example in FIG. 1B is described using a voltage controlled delay line, it is to be understood that a variety of different implementations of a controlled delay line may be used, including current controlled delay lines and digital controlled delay lines (i.e., a digital delay line, such as series connected inverters and a multiplexer, for example).

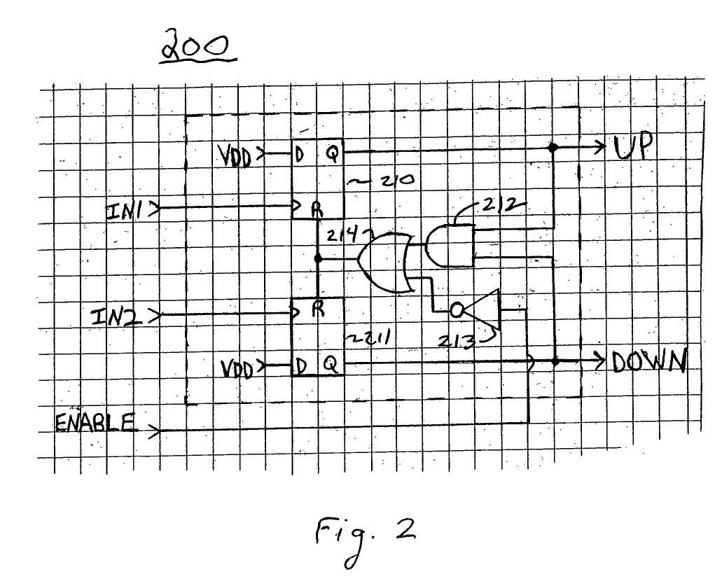

Controlled delay line circuit 100B includes an RC oscillator 161 coupled to a reference voltage controlled delay line 163 and an integrated transmission line 162. The reference voltage controlled delay line 163 is included in a feedback loop. In this example, the feedback loop also includes a phase detector 164, a charge pump 165, and a capacitor 166 (“C_{I}”). The voltage on C_{I}(i.e., V_{I}) is used to control both the reference voltage controlled delay line 163 and one or more other voltage controlled delay lines 167. A time difference between a first delayed signal from the transmission line 162 and a second delayed signal from the controlled delay line 163 may be translated into a voltage on a capacitor and used to control the first variable delay of delay line 163. The other voltage controlled delay line 167 may receive data and produce delayed data in accordance control voltage V_{I}. FIG. 2 is an example of a phase detector according to one embodiment of the present invention. The phase detector 200 in FIG. 2 is a phase-frequency detector including two D-type Flip Flops (“DFF”) 210 and 211, a reset circuit including an AND gate 212, and an enable circuit including an inverter 213. The reset and enable circuits are combined using a NOR gate 214 that drives the reset inputs of the DFFs. The phase detector of FIG. 2 is one possible way to implement the phase detector of FIG. 1B. In another embodiment, the phase detector may be implemented using the techniques described in U.S. patent application Ser. No. 11/200,472 filed on Aug. 8, 2004, entitled “Circuits and Methods for Reducing Static Phase Offset using Commutating Phase Detectors,” naming Paul William Ronald Self as Inventor, the entire disclosure of which is hereby incorporated herein by reference.

The integrated transmission line resides on the same monolithic silicon die along with all the circuitry contained within each of the functional blocks shown in FIG. 1B. Embodiments of the present invention include an implementation of a totally integrated delay locked loop that does not use the period of a system clock as the timing reference, but rather, an integrated transmission line is used as the timing reference device.

The present embodiment includes a variety of advantageous features for the delay locked loop that may be included to improve the performance of the DLL. Before describing the operation of FIG. 1B, such features will be described. In this example, a periodic reference signal is generated by RC oscillator 161 and provided to the inputs of the reference voltage controlled delay line 163 and an integrated transmission line 162. In other embodiments, a periodic signal may be generated by other circuits on the same integrated circuit or external to the integrated circuit and coupled to inputs of the transmission line and controlled delay line. During each period of the output signal of the RC oscillator (RCO), the amount of time that the RCO output signal is at a high logic level is larger than the flight time delay of the integrated transmission line. Further, the amount of time that the RCO output signal is at a high logic level is also larger than the longest possible time delay of the VCDL. An ENABLE function for the phase detector (PD) is another feature. In this embodiment, the PD includes an ENABLE function in order to guarantee that the phase detector correctly interprets the phase information from its inputs, IN1 and IN2. It is theoretically possible for the PD to incorrectly interpret the phase information at its inputs and then to continue to incorrectly interpret the phase relationship on subsequent cycles of the RC oscillator (RCO). By adding an ENABLE function to the PD, the PD is reset on every cycle by the RCO output signal, and thus, even if the PD incorrectly interprets the input phase relationship once, the ENABLE function will prevent it from continuing to incorrectly interpret the input phase relationship on subsequent cycles of the RCO.

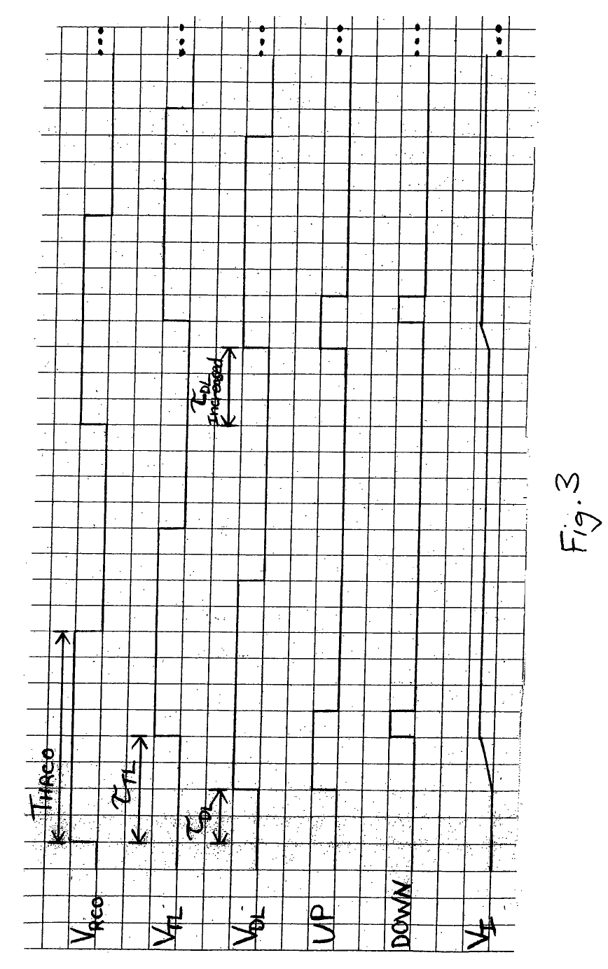

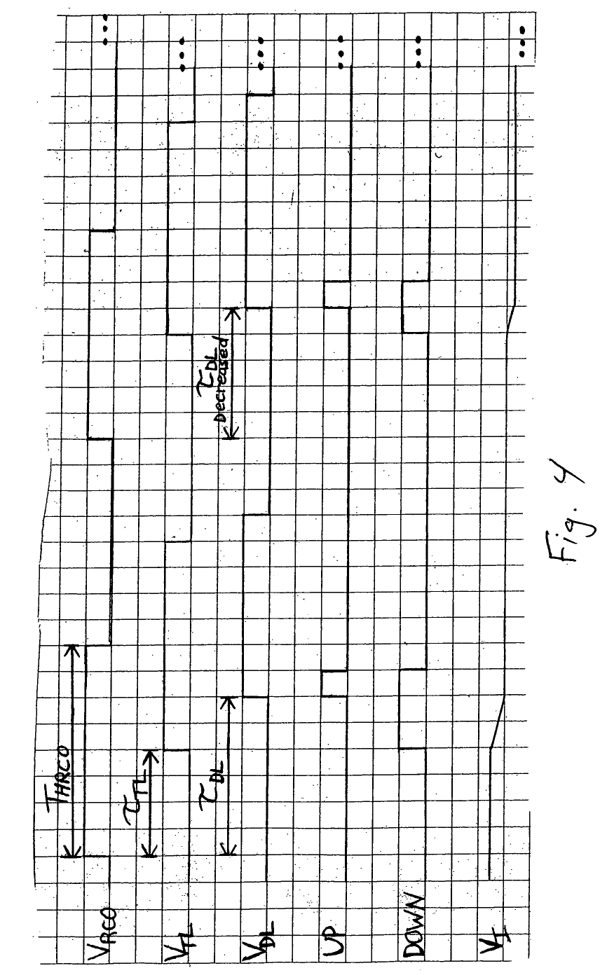

The operation of the invention can be understood by referring to timing diagrams found in FIG. 3 and FIG. 4. The timing diagram found in FIG. 3 illustrates the behavior of the circuit when the time delay of the VCDL, τ_{DL}, is smaller than the time delay of the integrated transmission line (ITL), τ_{TL}. V_{DL} is a delayed version of V_{RCO} with a time delay equal to τ_{DL}. V_{TL} is also a delayed version of V_{RCO} with a time delay equal to τ_{TL}. Initially, V_{RCO}, V_{TL}, V_{DL}, UP, and DOWN are all logic low. With V_{RCO} being low, the ENABLE function of the PD is de-asserted which forces the PD outputs, UP and DOWN, to logic low states. The first rising edge of V_{RCO} launches a rising edge into the two delay lines, the ITL and the VCDL. When V_{RCO} goes high, PD ENABLE becomes asserted which means that the outputs of the PD are allowed to change states as a function of the PD inputs, IN1 and IN2. Since τ_{DL} is shorter than τ_{TL}, the first rising edge that the PD responds to comes from V_{DL}. The rising edge of V_{DL} causes the UP output of the PD to go to a logic high level. An UP signal going high before the DOWN signal goes high indicates that the time delay of the VCDL needs to increase. A high logic level for the UP input of the charge pump (CP) causes the CP to turn on a charging current source connected to its output. The current source charges the capacitor C_{I} which results in a voltage ramp in the positive direction for V_{I}. When V_{TL} goes to a high logic level, the PD responds by forcing the DOWN output signal high. For a short amount of time both PD outputs, UP and DOWN, are at logic high levels simultaneously. When DOWN goes to a logic high, the CP will turn on a discharging current source that is connected to its output. While the UP and DOWN signals are both high, the CP's charging and discharging current sources are on simultaneously. Because the current sources are equal in value, the charging of Cᵢ ends and the positive voltage ramp of V_{I} stops. At this point the PD resets itself which results in both PD outputs, UP and DOWN, going to logic low levels simultaneously. At some point after the PD resets itself, V_{RCO} goes to a logic low which de-asserts the ENABLE function of the PD. The higher voltage of V_{I} causes the time delay of the VCDL to increase. This increase in τ_{DL} is shown in the timing diagram of FIG. 3. The end result is that the feedback loop has caused τ_{DL} to move in a direction to bring it closer in value to τ_{TL}.

The timing diagram found in FIG. 4 illustrates the behavior of the invention when the time delay of the VCDL, τ_{DL}, is longer than the time delay of the integrated transmission line (ITL), τ_{TL}. Just like the previous example initially, V_{RCO}, V_{TL}, V_{DL}, UP, and DOWN are all logic low. With V_{RCO} being low, the ENABLE function of the PD is de-asserted which forces the PD outputs, UP and DOWN, to logic low states. The first rising edge of V_{RCO} launches a rising edge into the two delay lines, the ITL and the VCDL. When V_{RCO} goes high, PD ENABLE becomes asserted which means that the outputs of the PD are allowed to change states as a function of the PD inputs, IN1 and IN2. Since τ_{DL} is longer than τ_{TL}, the first rising edge that the PD responds to comes from V_{TL}. The rising edge of V_{TL} causes the DOWN output of the PD to go to a logic high. A DOWN signal going high before the UP signal goes high indicates that the time delay of the VCDL needs to decrease. A high logic level for the DOWN input of the charge pump (CP) causes the CP to turn on a discharging current source connected to its output. The current source discharges the capacitor C_{I} which results in a voltage ramp in the negative direction for V_{I}. When V_{DL} goes to a high logic level, the PD responds by forcing the UP output signal high. For a short amount of time both PD outputs, UP and DOWN, are at logic high levels simultaneously. When UP goes to a logic high, the CP will turn on a charging current source that is connected to its output. While the UP and DOWN signals are both high, the CP's charging and discharging current sources are on simultaneously. Because the current sources are equal in value, the discharging of C_{I} ends and the negative voltage ramp of V_{I} stops. At this point the PD resets itself which results in both PD outputs, UP and DOWN, going to logic low levels simultaneously. At some point after the PD resets itself, V_{RCO} goes to a logic low which de-asserts the ENABLE function of the PD. The lower voltage of V_{I} causes the time delay of the VCDL to decrease. This decrease in τ_{DL} is shown in the timing diagram of FIG. 4. Again, the end result is that the feedback loop of the invention has caused τ_{DL} to move in a direction to bring it closer in value to τ_{TL}.

In the manner described in the previous two paragraphs, the feedback loop will gradually adjust V_{I} and the time delay of the voltage controlled delay line until the value of τ_{DL} matches the flight time delay of the integrated transmission line. The examples illustrated in FIGS. 3-4 are commonly referred to as delay locked loops. Thus, one can see that an integrated transmission line can be used as a timing reference device for a completely integrated feedback loop.

The above description illustrates various embodiments of a controlled delay line with an integrated transmission line reference along with examples of how aspects of the present invention may be implemented. The above examples and embodiments are presented to illustrate the flexibility and advantages of the present invention as defined by the following claims. Based on the above disclosure and the following claims, other arrangements, embodiments, implementations and equivalents will be evident to those skilled in the art and may be employed without departing from the spirit and scope of the invention as defined by the claims.

What is claimed is:

1. An integrated circuit comprising:
a first controlled delay line coupled in a feedback loop; and
an integrated transmission line,
wherein the integrated transmission line is used as a timing reference for the feedback loop and wherein the feedback loop and the transmission line are integrated on a single integrated circuit.

2. The circuit of claim 1 wherein the feedback loop includes a phase detector having a first input coupled to an output of the integrated transmission line and a second input coupled to an output of the first controlled delay line.

3. The circuit of claim 1 wherein the first controlled delay line and the integrated transmission line have inputs that are coupled to a circuit that generates a first periodic signal.

4. The circuit of claim 1 further comprising:
a phase-frequency detector having a first input coupled to an output of the integrated transmission line and a second input coupled to an output of the first controlled delay line;
a charge pump coupled to an output of the phase-frequency detector; and
a capacitor coupled to the output of the charge pump and to a control input of the first controlled delay line.

5. The circuit of claim 1 further comprising a second controlled delay line having a control input coupled to the control input of the first controlled delay line.

6. The circuit of claim 5 wherein the second controlled delay line receives an input signal, and generates a delayed version of said input signal.

7. An integrated circuit comprising:
an integrated transmission line having an input coupled to receive a periodic signal, the transmission line delaying the periodic signal by a first delay to produce a first delayed signal;
a first controlled delay line having a first input coupled to the periodic signal and a first control input, the first controlled delay line delaying the periodic signal by a first variable delay to produce a second delayed signal;
a phase detector having a first input coupled to an output of the integrated transmission line and a second input coupled to an output of the first controlled delay line; and
a filter coupled between an output of the phase detector and the control input of the first controlled delay line.

8. The circuit of claim 7 wherein the phase detector, the first controlled delay line, and the transmission line are integrated on a single integrated circuit.

9. The circuit of claim 7 wherein the integrated transmission line comprises one or more conductive interconnect layers.

10. The circuit of claim 7 wherein the filter comprises a capacitor.

11. The circuit of claim 7 further comprising a second controlled delay line having a control input coupled to the filter.

12. The circuit of claim 7 wherein the phase detector is a phase-frequency detector coupled to a charge pump.

13. The circuit of claim 12 wherein the periodic signal is generated by an oscillator circuit, and the phase-frequency detector includes an enable input coupled to the oscillator circuit.

14. An integrated circuit comprising:
transmission line means for delaying a periodic reference signal means by a fixed amount of time;
controlled delay line means for delaying the periodic reference signal means by a first variable amount of time; and
feedback loop means for adjusting the first variable amount of time to equal the fixed amount of time,
wherein the transmission line means, the controlled delay line means, and the feedback loop means are integrated on a single integrated circuit.

15. A method of controlling the delay of a signal comprising:
generating a first signal:
delaying the first signal by a first delay in an integrated transmission line to produce a first delayed signal; and
delaying the first signal by a first variable delay in a first controlled delay line to produce a second delayed signal, wherein the first controlled delay line is configured in a feedback loop,
wherein the integrated transmission line is used as a timing reference for the feedback loop to adjust the first variable delay to be equal to the first delay, and wherein the feedback loop and the transmission line are integrated on a single integrated circuit.

16. The method of claim 15 further comprising delaying a second signal by a second variable delay in a second controlled delay line.

17. The method of claim 16 wherein the second variable delay is equal to the first variable delay.

18. The method of claim 15 further comprising detecting a phase difference between the first delayed signal and the second delayed signal.

19. The method of claim 15 further comprising increasing the first variable delay if the first delay is greater than the first variable delay, and decreasing the first variable delay if the first delay is smaller than the first variable delay.

20. The method of claim 15 wherein a time difference between the first delayed signal and the second delayed signal is translated into a voltage on a capacitor and used to control the first variable delay.

21. The method of claim 15 further comprising:
generating a first pulse in response to the first delayed signal and generating a second pulse in response to the second delayed signal;
discharging a current from a capacitor in response to receiving the first pulse, and charging a current into a capacitor in response to receiving the second pulse, and in accordance therewith, changing a first voltage on the capacitor; and
adjusting the first variable delay using the first voltage on the capacitor.
